(19) United States
(12) Patent Application Publication
(10) Pub. No.: US 2026/0040630 A1
(43) Pub. Date: Feb. 5, 2026

(54) SEMICONDUCTOR DEVICE, METHOD OF MANUFACTURING THE SEMICONDUCTOR DEVICE, AND MEMORY DEVICE INCLUDING THE SEMICONDUCTOR DEVICE

(71) Applicant: Samsung Electronics Co., Ltd., Suwon-si (KR)

(72) Inventors: Sijung YOO, Suwon-si (KR); Donghoon KIM, Suwon-si (KR); Dukhyun CHOE, Suwon-si (KR)

(73) Assignee: Samsung Electronics Co., Ltd., Suwon-si (KR)

(21) Appl. No.: 19/009,116

(22) Filed: Jan. 3, 2025

(30) Foreign Application Priority Data
Aug. 2, 2024 (KR) 10-2024-0103274

(51) Int. Cl. H10D 30/69; H10B 51/10; H10B 51/20; H10D 30/01; H10D 62/80; H10D 64/01; H10D 64/68

(52) U.S. Cl. CPC H10D 30/701; H10B 51/10; H10B 51/20; H10D 30/0415; H10D 62/883; H10D 64/033; H10D 64/689

(57) ABSTRACT

Provided are a semiconductor device, a method of manufacturing the semiconductor device, and a memory device including the semiconductor device. The semiconductor device includes a channel layer, an insulating layer on the channel layer, an intermediate electrode on the insulating layer, a mixed layer provided on the intermediate electrode and including a discontinuous ferroelectric and a low-k dielectric material filled between regions of the discontinuous ferroelectric, the low-k dielectric material having a dielectric constant less than a dielectric constant of the discontinuous ferroelectric, a gate electrode on the mixed layer, and a two-dimensional (2D) material layer provided in at least region selected from a region between the intermediate electrode and the mixed layer and a region between the gate electrode and the mixed layer.

### CROSS-REFERENCE TO RELATED APPLICATION

This application is based on and claims priority under 35 U.S.C. § 119 to Korean Patent Application No. 10-2024-0103274, filed on Aug. 2, 2024, in the Korean Intellectual Property Office, the disclosure of which is incorporated by reference herein in its entirety.

### BACKGROUND

### 1. Field

The disclosure relates to a semiconductor device, a method of manufacturing the semiconductor device, and a memory device including the semiconductor device.

### 2. Description of the Related Art

Ferroelectrics are materials exhibiting ferroelectricity, wherein spontaneous polarization is achieved by aligning the internal electric dipole moments of the material such that, even when no electric field is applied thereto from the outside, the internal electric dipole moments remain aligned. Recently, research has been conducted into applying ferroelectric field effect transistors (FeFETs) to memory devices. FeFETs are semiconductor devices having memory characteristics by using a ferroelectric material as a gate insulating layer to control a threshold voltage according to the polarization direction of the ferroelectric material. FeFETs have characteristics such as relatively low operating voltage and a relatively high programming speed.

### SUMMARY

Provided are a semiconductor device, a method of manufacturing the semiconductor device, and a memory device including the semiconductor device.

Additional aspects will be set forth in part in the description which follows and, in part, will be apparent from the description, or may be learned by practice of the presented embodiments of the disclosure.

According to an aspect of the disclosure, a semiconductor device includes: a channel layer; a gate electrode spaced apart from the channel layer; an insulating layer on between the channel layer and the gate electrode; an intermediate electrode between on the insulating layer and the gate electrode; a mixed layer provided on between the intermediate electrode and the gate electrode, and the mixed layer comprising a discontinuous ferroelectric and a low-k dielectric material filled between regions of the discontinuous ferroelectric, the low-k dielectric material having a dielectric constant less than a dielectric constant of the discontinuous ferroelectric; a gate electrode on the mixed layer; and a two-dimensional (2D) material layer provided in at least region selected from a region between the mixed layer and at least one of the intermediate electrode and the mixed layer and a region between or the gate electrode and the mixed layer.

The discontinuous ferroelectric may include at least one of HfO₂, ZrO₂, or HfₓZr₁₋ₓO₂ (0<x<1).

The discontinuous ferroelectric may further include a dopant.

The dopant may include at least one of lanthanum (La), yttrium (Y), gadolinium (Gd), silicon (Si), aluminum (Al), magnesium (Mg), strontium (Sr), or barium (Ba).

An area proportion of the discontinuous ferroelectric in the mixed layer may be within a range of about 0.1 to about 0.8.

The low-k dielectric material may include at least one of SiO₂ or SiOC.

The insulating layer may include a high-k dielectric material having a dielectric constant greater than the dielectric constant of the low-k dielectric material.

The high-k dielectric material may include at least one of HfO₂, ZrO₂, Ta₂O₅, or TiO₂.

The 2D material layer may include at least one of graphene, transition metal dichalcogenide (TMD), or hexagonal boron nitride (h-BN).

The mixed layer may have a different area from the insulating layer when view in a plan view.

The 2D material layer may include an exposure pattern exposing the intermediate electrode or the gate electrode.

According to another aspect of the disclosure, a memory device includes a plurality of memory cells arranged in a direction perpendicular to a substrate each of the plurality of memory cells comprises a channel layer, a gate electrode spaced apart from the channel layer and extending in the direction perpendicular to the substrate, an insulating layer between the channel layer and the gate electrode, an intermediate electrode between the insulating layer and the gate electrode, a mixed layer between the intermediate electrode and the gate electrode, the mixed layer comprising a discontinuous ferroelectric and a low-k dielectric material, the discontinuous ferroelectric being provided on the gate electrode, the low-k dielectric material being filled between regions of the discontinuous ferroelectric and having a dielectric constant less than a dielectric constant of the discontinuous ferroelectric, and a two-dimensional (2D) material layer between the mixed layer and at least one of the intermediate electrode or the gate electrode.

The discontinuous ferroelectric may include at least one of HfO₂, ZrO₂, or HfₓZr₁₋ₓO₂ (0<x<1).

The discontinuous ferroelectric may further include a dopant.

The insulating layer may include a high-k dielectric material having a dielectric constant greater than the dielectric constant of the low-k dielectric material.

The 2D material layer may include at least one of graphene, transition metal dichalcogenide (TMD), or hexagonal boron nitride (h-BN).

The 2D material layer may include an exposure pattern exposing the intermediate electrode or the gate electrode.

According to another aspect of the disclosure, there is provided a method of manufacturing a mixed layer a semiconductor device including a channel layer, an insulating layer, an intermediate electrode, the mixed layer, and a gate electrode sequentially stacked, the method including: depositing a 2D material layer on at least one of the intermediate electrode or the gate electrode; and forming the mixed layer on the 2D material layer, wherein the forming of the mixed layer includes: growing a ferroelectric discontinuously on the 2D material layer, and forming a low-k dielectric material between regions of the discontinuously-grown ferroelectric.

The 2D material layer may include at least one of graphene, transition metal dichalcogenide (TMD), or hexagonal boron nitride (h-BN).

The ferroelectric may include at least one of HfO₂, ZrO₂ or HfₓZr₁₋ₓO₂ (0<x<1).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a semiconductor device according to at least one embodiment;

FIG. 2 shows a transmission electron microscopy bright field (TEM BF) image of a thin HfZrO film discontinuously grown on graphene by atomic layer deposition (ALD);

FIG. 3 is a cross-sectional view illustrating a semiconductor device according to a comparative example;

FIG. 4 is a graph showing a capacitance ratio of the semiconductor device of at least one embodiment to the semiconductor device of a comparative example with respect to a coverage ratio of a thin HfZrO film;

FIG. 5 is a cross-sectional view illustrating a semiconductor device according to another embodiment;

FIG. 6 is a cross-sectional view illustrating a semiconductor device according to another embodiment;

FIG. 7 is a plan view illustrating a two-dimensional (2D) material layer shown in FIG. 6;

FIG. 8 is a cross-sectional view illustrating a semiconductor device according to another embodiment;

FIG. 9 is a perspective view illustrating a semiconductor device according to another embodiment;

FIG. 10 is a cross-sectional view taken along line I-I′ of FIG. 9;

FIG. 11 is a perspective view illustrating a memory device according to at least one embodiment;

FIG. 12 is a plan view illustrating the memory device shown in FIG. 11;

FIG. 13 is a cross-sectional view taken along line II-II′ of FIG. 12;

FIG. 14 is a conceptual view schematically illustrating a device architecture applicable to electronic devices according to embodiments;

FIG. 15 is a block diagram illustrating a memory system according to at least one embodiment; and

FIG. 16 is a block diagram illustrating a neuromorphic device and an external device connected to the neuromorphic device, according to at least one embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described with reference to the accompanying drawings. In the drawings, like reference numerals refer to like elements, and the sizes of elements may be exaggerated for clarity of illustration. The embodiments described herein are for illustrative purposes only, and various modifications may be made therein. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, “included in” the range of “X” to “Y” includes all values between X and Y, including X and Y.

In the following description, when an element is referred to as being “above” or “on” another element, it may be directly on an upper, lower, left, or right side of the other element while making contact with the other element or may be above an upper, lower, left, or right side of the other element without making contact with the other element. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary, and are not limited to the stated order thereof.

In the disclosure, terms such as “unit” or “module” may be used to denote a unit that has at least one function or operation and is implemented with and/or enabled by processing circuitry such as hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. Additionally, elements included in units may be configured to be in communication with each other, e.g., through wires, vias, a bus, and/or the like.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples or exemplary terms are just used herein to describe technical ideas and should not be considered for purposes of limitation unless defined by the claims.

Ferroelectric field effect transistors (FeFETs) are semiconductor devices that have nonvolatile memory characteristics by utilizing a phenomenon in which a threshold voltage of a transistor varies with spontaneous polarization switching. FeFETs may have a minimum threshold voltage and a maximum threshold voltage that are determined by the polarization state of a ferroelectric, and the difference between the minimum and maximum threshold voltages may be referred as a memory window (MW) and corresponds to a sensing margin. As such, it is beneficial to increase and/or maximize the MWs of FeFETs.

The MW of an FeFET having a metal-ferroelectric-metal-insulator-semiconductor (MFMIS) structure is determined by the ratio of the capacitance C_{FE} of a metal-ferroelectric-metal (MFM) capacitor and the capacitance C_{Ins} of a metal-insulator-semiconductor (MIS) capacitor, and tends to increase as the C_{FE}/C_{Ins} ratio decreases. Therefore, the MW of an FeFET having an MFMIS structure may be increased by reducing the capacitance C_{FE} of an MFM capacitor containing a ferroelectric.

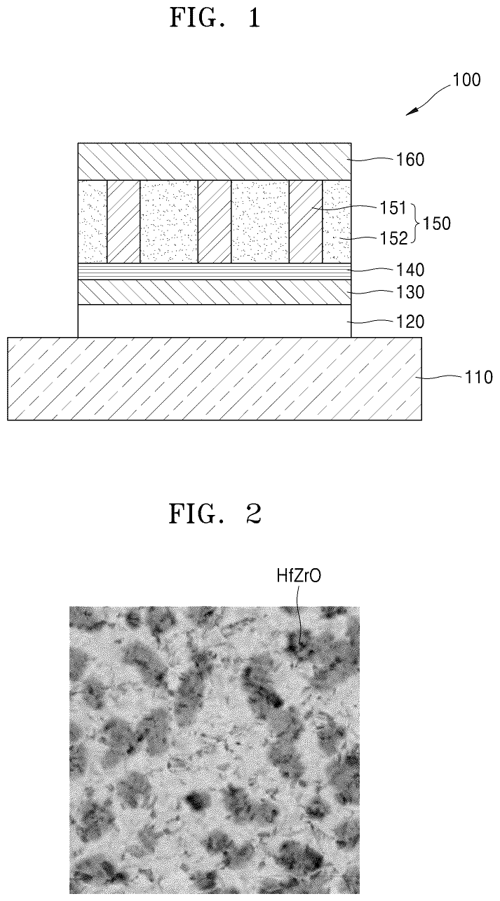

FIG. 1 is a cross-sectional view illustrating a semiconductor device 100 according to at least one embodiment. The semiconductor device 100 illustrated in FIG. 1 may be an FeFET having an MFMIS structure. The semiconductor device 100 may form one of a plurality of memory cells included in a memory device.

Referring to FIG. 1, the semiconductor device 100 may include a channel layer 110, an insulating layer 120, an intermediate electrode 130, a 2D (two-dimensional) material layer 140, a mixed layer 150, and a gate electrode 160 that are sequentially stacked. In the channel layer 110, a channel element (or region) corresponding to the gate electrode 160 may be formed, and a source region (not shown) and a drain region (not shown) may be formed on respective sides of the channel element. The source and drain regions may be electrically connected to a source electrode (not shown) and a drain electrode (not shown), respectively.

The channel layer 110 may include, for example, an elemental semiconductor (e.g., a Group IV semiconductor such as Si, Ge, or SiGe), a compound semiconductor (e.g., a Group III-V compound semiconductor), an oxide semiconductor, a nitride semiconductor, an oxynitride semiconductor, a 2D semiconductor material, quantum dots, and/or an organic semiconductor. However, this is merely illustrative, and embodiments are not limited thereto. The channel layer 110 may further include a dopant. Here, the dopant may include a p-type dopant and/or an n-type dopant. For example, for a Group IV semiconductor, the p-type dopant may include, for example, a Group III element such as B, Al, Ga, or In, and the n-type dopant may include, for example, a Group V element such as P, As, or Sb. The channel layer 110 may be formed as part of a semiconductor substrate or separately from the semiconductor substrate.

The gate electrode 160 is provided above and space apart from the channel layer 110. The gate electrode 160 may include a conductive material. For example, the conductive material of the gate electrode 160 may include a metal, a metal nitride, a metal oxide, polysilicon, a metal carbide, a two-dimensional (2D) conductive material, and/or a conductive combination thereof. For example, the gate electrode 160 may include at least one of W, TiN, TaN, WN, NbN, Mo, Ru, Ir, RuO, IrO, and/or heavily doped polysilicon.

In at least some embodiments, the metal carbide may be a metal carbide doped with aluminum or silicon. For example, the metal carbide may include at least one of TiAlC, TaAlC, TiSiC, or TaSiC. The gate electrode 160 may have a structure in which a plurality of materials are stacked. For example, the gate electrode 160 may have a stacked structure of a metal nitride layer/metal layer, such as a TiN/Al structure, or may have a stacked structure of a metal nitride layer/metal carbide layer/metal layer, such as a TiN/TiAlC/W structure.

The intermediate electrode 130 is provided between the channel layer 110 and the gate electrode 160. Like the gate electrode 160, the intermediate electrode 130 may include a conductive material. For example, the intermediate electrode 130 may include at least one selected from W, TIN, TaN, WN, NbN, Mo, Ru, Ir, RuO, IrO, and/or polysilicon. The intermediate electrode 130 may include the same conductive material as the gate electrode 160 or a conductive material different from the conductive material included in the gate electrode 160.

The mixed layer 150 includes a discontinuous ferroelectric 151 and is provided between the intermediate electrode 130 and the gate electrode 160, and the 2D material layer 140 is provided between the intermediate electrode 130 and the mixed layer 150. The 2D material layer 140 may have a thickness of about 0.3 nanometers (nm) to about 3 nm in the stacking direction, and the mixed layer 150 may have a thickness of about 3 nm to about 20 nm in the stacking direction. However, the examples embodiments are not limited thereto.

The 2D material layer 140 refers to a material having a layered structure in which constituent atoms are bonded together in a 2D form. The 2D material layer 140 may have a monolayer or multilayer structure, and each layer of the 2D material layer 140 may have an approximately atomic-level thickness. In at least some embodiments, the monolayer and/or the layers in the multi-layer structure may include be substantially parallel to an upper surface of the intermediate electrode 130. The 2D material layer 140 may serve as a seed layer that induces a discontinuous growth of the ferroelectric 151 as described below.

The 2D material layer 140 may include, for example, graphene, hexagonal boron nitride (h-BN), and/or transition metal dichalcogenide (TMD). However, embodiments are not limited thereto. Graphene refers a 2D material with conductivity, in which carbon atoms are connected in a 2D hexagonal structure. The graphene may include intrinsic graphene with a crystal size greater than about 100 nm and/or nanocrystalline graphene with a crystal size greater than or equal to about 100 nm. h-BN refers to a 2D material with insulating properties, in which boron and nitrogen atoms are connected in a 2D hexagonal structure.

TMD refers to a 2D material with semiconductor properties, in which a transition metal and a chalcogen element form a compound. Here, the transition metal may include, for example, at least one selected from Mo, W, Nb, V, Ta, Ti, Zr, Hf, Co, Tc, and Re, and the chalcogen element may include, for example, at least one selected from S, Se, and Te. Examples of the TMD may include MoS₂, MoSe₂, MoTe₂, WS₂, WSc₂, WTe₂, ZrS₂, ZrSc₂, HfS₂, HfSc₂, NbSe₂, ReSc₂, and/or the like.

The mixed layer 150 is provided between the 2D material layer 140 and the gate electrode 160. The mixed layer 150 may include the discontinuous ferroelectric 151 and a low-k dielectric material 152 formed between regions of the discontinuous ferroelectric 151. The ferroelectric 151 refers to a material with ferroelectricity, in which spontaneous polarization may be maintained due to the alignment of internal electric dipole moments. More specifically, the ferroelectric 151 has remnant polarization due to the dipoles even when no external electric field is applied to the ferroelectric 151. In ferroelectrics, the direction of polarization may be switched in units of domains by an external electric field.

The ferroelectric 151 may include, for example, a material with fluorite-based structure (hereafter referred to as a “fluorite-based material”). For example, the ferroelectric 151 may include at least one selected from hafnium oxide (HfO₂), zirconium oxide (ZrO₂), and hafnium-zirconium oxide (HfₓZr₁₋ₓO₂, 0<x<1). The ferroelectric 151 may further include a dopant. The dopant may include, for example, at least one selected from La, Y, Gd, Si, Al, Mg, Sr, and Ba, but it is not limited thereto. The fluorite-based material may comprise a ferroelectric phase (e.g., a crystal phase lacking an inversion center (e.g., is non-centrosymmetric)) in the largest proportion among all crystal phases and/or as a dominant phase. In at least some embodiments, the ferroelectric 151 may include at least one crystal phase selected from an orthorhombic crystal phase, a tetragonal crystal phase, and a monoclinic crystal phase. For example, the ferroelectric 151 may include the orthorhombic crystal phase as a dominant phase and/or in the largest proportion among all crystal phases).

The ferroelectric 151 is discontinuously formed in the mixed layer 150. For example, the ferroelectric 151 may be formed in the mixed layer 150 in an island-like pattern (e.g., the ferroelectric 151 may comprising a plurality of regions (or islands) in the mixed layer 150). The ferroelectric 151 may discontinuously grow from the 2D material layer 140. That is, the 2D material layer 140 may serve as a seed layer that induces a discontinuous growth of the ferroelectric 151.

The 2D material layer 140 may have defects, and the ferroelectric 151 may grow from the defects of the 2D material layer 140 and may thus have a discontinuous shape. Here, for example, the area proportion of the discontinuous ferroelectric 151 in the mixed layer 150 (i.e., the ratio of an area of the 2D material layer 140 covered by the discontinuous ferroelectric 151 to the total area of the 2D material layer 140) may be from about 0.1 to about 0.8 (for example, from about 0.12 to about 0.6). For example, the defects may serve as nucleation sites for the growth of the ferroelectric 151, and the formation of the defects and/or the grain growth of the ferroelectric 151 may be controlled such that the ferroelectric 151 has the discontinuous shape. Additionally, regions of the 2D material layer 140 without defects may hinder (and/or prevent) nucleation, adhesion, and/or grain growth of the ferroelectric 151. The discontinuous ferroelectric 151 may be formed, for example, by atomic layer deposition (ALD), but is not limited thereto.

FIG. 2 shows a transmission electron microscopy bright field (TEM BF) image of a thin HfZrO film discontinuously grown on graphene by ALD. Referring to FIG. 2, it may be seen that the thin HfZrO film is grown on the graphene in an island-like pattern.

In the mixed layer 150, the low-k dielectric material 152 having a lower dielectric constant than the discontinuous ferroelectric 151 may be filled between regions of the discontinuous ferroelectric 151. The low-k dielectric material 152 may include, for example, at least one selected from SiO₂ and SiOC, but it is not limited thereto.

The mixed layer 150 including the discontinuous ferroelectric 151 and the low-k dielectric material 152 filled between regions of the ferroelectric 151 may be formed as follows. The 2D material layer 140 is deposited on the intermediate electrode 130. Here, the 2D material layer 140 may serve as a seed layer that induces a discontinuous growth of the ferroelectric 151 as described above. For example, the 2D material layer 140 may be formed to a thickness of about 0.3 nm to about 3 nm. Next, the ferroelectric 151 is grown on the 2D material layer 140. In this process, the ferroelectric 151 may be grown from defects of the 2D material layer 140 and may thus have a discontinuous shape (for example, an island-like pattern). Then, the low-k dielectric material 152 may be deposited between regions of the discontinuous ferroelectric 151, thereby forming the mixed layer 150 including the discontinuous ferroelectric 151 and the low-k dielectric material 152. Here, for example, the area proportion of the discontinuous ferroelectric 151 in the mixed layer 150 may be from about 0.1 to about 0.8 (for example, from about 0.12 to about 0.6). For example, the mixed layer 150 may have a thickness of about 3 nm to about 20 nm.

The insulating layer 120 is provided between the channel layer 110 and the intermediate electrode 130. The insulating layer 120 may include a high-k dielectric material having a dielectric constant greater than the dielectric constant of the low-k dielectric material 152. For example, the high-k dielectric material may include at least one selected from HfO₂, ZrO₂, Ta₂O₅, and TiO₂, but is not limited thereto.

In the semiconductor device 100 the mixed layer 150 including the discontinuous ferroelectric 151 and the low-k dielectric material 152 filled between regions of the discontinuous ferroelectric 151 is provided between the gate electrode 160 and the intermediate electrode 130, and thus, the capacitance C_{FE} of an MFM capacitor formed by the gate electrode 160, the mixed layer 150 including the discontinuous ferroelectric 151, and the intermediate electrode 130 may be reduced. For example, the mixed layer 150 provided between the gate electrode 160 and the intermediate electrode 130 includes the discontinuous ferroelectric 151, and the discontinuous ferroelectric 151 has an effect of connecting the gate electrode 160 and the intermediate electrode 130 in parallel to each other, thereby reducing the capacitance C_{FE} of the MFM capacitor. As a result, the MW of the semiconductor device 100 may increase.

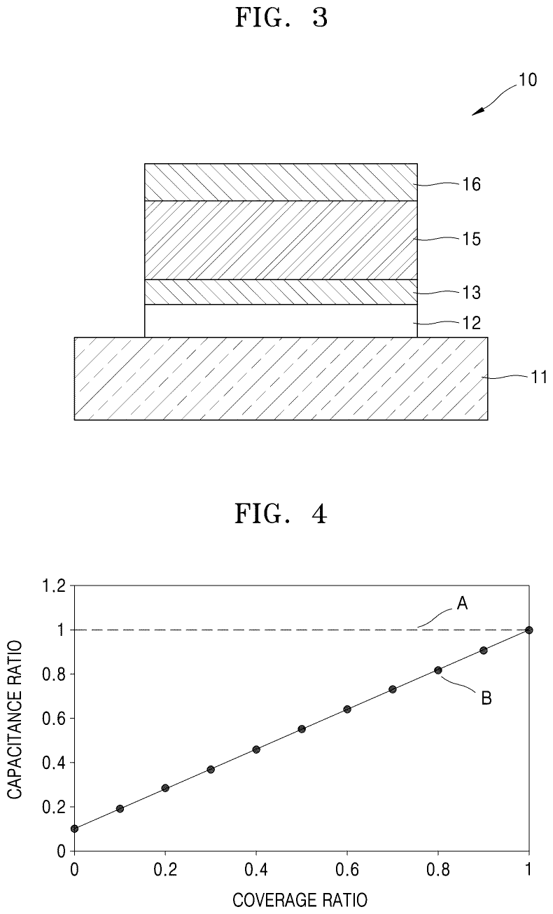

FIG. 3 is a cross-sectional view illustrating a semiconductor device 10 according to a comparative example. The semiconductor device shown in FIG. 3 may be an FeFET having an MFMIS structure.

Referring to FIG. 3, the semiconductor device 10 includes a channel layer 11, an insulating layer 12, an intermediate electrode 13, a ferroelectric layer 15, and a gate electrode 16 that are sequentially stacked. Here, the descriptions of the channel layer 11, the insulating layer 12, the intermediate electrode 13, and the gate electrode 16 are respectively the same as the channel layer 110, the insulating layer 120, the intermediate electrode 130, and the gate electrode 160 of the previous embodiment, and thus, repeated descriptions thereof are omitted.

The ferroelectric layer 15 is provided between the intermediate electrode 13 and the gate electrode 16. Here, the ferroelectric layer 15 includes a ferroelectric that is continuously formed. The ferroelectric may include at least one selected from hafnium oxide (HfO₂), zirconium oxide (ZrO₂), and hafnium-zirconium oxide (HfₓZr₁₋ₓO₂, 0<x<1). In addition, the ferroelectric may further include a dopant including at least one selected from, for example, La, Y, Gd, Si, Al, Mg, Sr, and Ba.

FIG. 4 is a graph showing the capacitance ratio of the semiconductor device 100 and the semiconductor device 10 of the comparative example, with respect to the coverage ratio of a thin HfZrO film. In the semiconductor device 10 of the comparative example, HfZrO is used as a ferroelectric, whereas in the semiconductor device 100 of the embodiment, graphene is used as a 2D material, and HfZrO is as a ferroelectric.

In FIG. 4, the “capacitance ratio” refers to the ratio of the capacitance of the semiconductor device 100 of the embodiment shown in FIG. 1 to the capacitance of the semiconductor device 10 of the comparative example shown in FIG. 3. For example, FIG. 4 shows the capacitance B of the semiconductor device 100 of the embodiment shown in FIG. 1 when the capacitance A of the semiconductor device 10 of the comparative example shown in FIG. 3 is 1. The “coverage ratio” refers to the ratio of the area of the 2D material layer 140 covered by the discontinuous ferroelectric 151 in the semiconductor device 100 of the embodiment shown in FIG. 1.

FIG. 4 shows that as the coverage ratio of the thin HfZrO film decreases, the capacitance C_{FE} of the MFM capacitor gradually decreases.

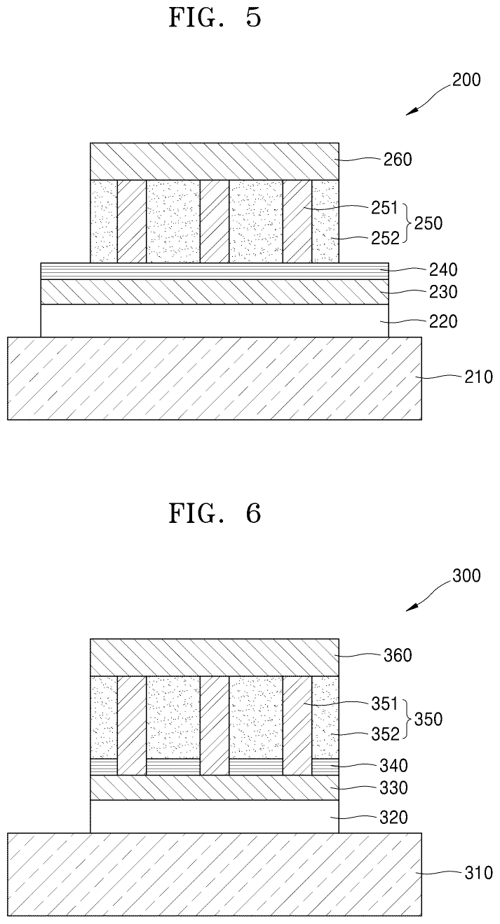

FIG. 5 is a cross-sectional view illustrating a semiconductor device 200 according to another embodiment. The differences from the previous embodiment will be mainly described below.

Referring to FIG. 5, the semiconductor device 200 may include a channel layer 210, an insulating layer 220, an intermediate electrode 230, a 2D material layer 240, a mixed layer 250, and a gate electrode 260 that are sequentially stacked. Here, the mixed layer 250 may include a discontinuous ferroelectric 251 and a low-k dielectric material 252 filled between regions of the discontinuous ferroelectric 251. The description of the channel layer 210, the insulating layer 220, the intermediate electrode 230, the 2D material layer 240, the mixed layer 250, and the gate electrode 260 are substantially similar to the channel layer 110, the insulating layer 120, the intermediate electrode 130, the 2D material layer 140, the mixed layer 150, and the gate electrode 160 described above, and thus, repeated descriptions thereof are omitted.

In the current embodiment, the mixed layer 250 and/or the gate electrode 260 may each have a different area from the insulating layer 220 in a plan view. For example, the mixed layer 250 may have a smaller area than the insulating layer 220. As described above, the area of the mixed layer 250 of an MFM capacitor formed by the gate electrode 260, the mixed layer 250, and the intermediate electrode 230 is smaller than the area of the insulating layer 220 of an MIS capacitor formed by the intermediate electrode 230, the insulating layer 220, and the channel layer 210. Thus, the capacitance C_{FE} of the MFM capacitor may be further reduced compared to the previous embodiment, and as a result, the MW of the semiconductor device 200 may be further increased.

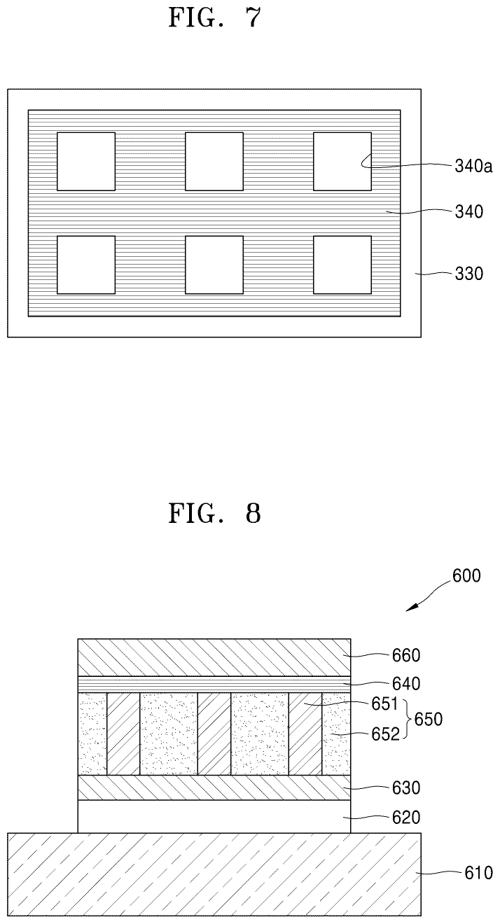

FIG. 6 is a cross-sectional view illustrating a semiconductor device 300 according to another embodiment. FIG. 7 is a plan view illustrating a 2D material layer 340 shown in FIG. 6.

Referring to FIGS. 6 and 7, the semiconductor device 300 may include a channel layer 310, an insulating layer 320, an intermediate electrode 330, a 2D material layer 340, a mixed layer 350, and a gate electrode 360 that are sequentially stacked. The channel layer 310, the insulating layer 320, the intermediate electrode 330, and the gate electrode 360 are substantially similar to the channel layer 110, the insulating layer 120, the intermediate electrode 130, the 2D material layer 140, the mixed layer 150, and the gate electrode 160, and thus, repeated descriptions thereof are omitted.

The 2D material layer 340 is patterned on the intermediate electrode 330. As shown in FIG. 7, an exposure pattern 340a having a predetermined shape is formed in the 2D material layer 340, and an upper surface of the intermediate electrode 330 is exposed through the exposure pattern 340a. The exposure pattern 340a may be formed by depositing a 2D material on the intermediate electrode 330 and then removing portions of the deposited 2D material in the predetermined pattern. For example, regions of the 2D material that contain defects may be removed through patterning. Therefore, the patterned 2D material layer 340 may have substantially no defects on which a ferroelectric 351 (described later) may grow.

The mixed layer 350 is provided on the patterned 2D material layer 340. The mixed layer 350 may include the discontinuous ferroelectric 351 and a low-k dielectric material 352 filled between regions of the discontinuous ferroelectric 351. As described above, the patterned 2D material layer 340 has substantially no defects, and thus, the ferroelectric 351 may not grow on the patterned 2D material layer 340 but may grow from the intermediate electrode 330 exposed through the exposure pattern 340a. In this manner, the discontinuous ferroelectric 351 may be formed. Then, the low-k dielectric material 352 may be grown on the patterned 2D material layer 340 to fill a space between the regions of the discontinuous ferroelectric 351.

FIG. 8 is a cross-sectional view illustrating a semiconductor device 600 according to another embodiment.

Referring to FIG. 8, the semiconductor device 600 may include a channel layer 610, an insulating layer 620, an intermediate electrode 630, a mixed layer 650, a 2D material layer 640, and a gate electrode 660 that are sequentially stacked. The channel layer 610, the insulating layer 620, the intermediate electrode 630, and the gate electrode 660 are substantially similar to the channel layer 110, the insulating layer 120, the intermediate electrode 130, the 2D material layer 140, the mixed layer 150, and the gate electrode 160 described above, and thus, repeated descriptions thereof are omitted.

The mixed layer 650 including a discontinuous ferroelectric 651 is provided between the intermediate electrode 630 and the gate electrode 660, and the 2D material layer 640 is provided between the gate electrode 660 and the mixed layer 650. After forming the 2D material layer 640 on the gate electrode 660, the mixed layer 650 may be formed on the 2D material layer 640. Here, the 2D material layer 640 may serve as a seed layer that induces a discontinuous growth of the ferroelectric 651. The mixed layer 650 is provided between the 2D material layer 640 and the intermediate electrode 630. The mixed layer 650 may include the discontinuous ferroelectric 651 and a low-k dielectric material 652 filled between regions of the discontinuous ferroelectric 651.

In the semiconductor device 600 the 2D material layer 640 may be formed on the gate electrode 660, and then, the mixed layer 650 may be formed on the 2D material layer 640. Here, the mixed layer 650 may be formed by forming the discontinuous ferroelectric 651 on the 2D material layer 640 in a discontinuous form and then depositing the low-k dielectric material 652 between regions of the discontinuous ferroelectric 651.

FIG. 8 illustrates an example in which the mixed layer 650 including the discontinuous ferroelectric 651 has the same area as the insulating layer 620. However, embodiments are not limited thereto, and the mixed layer 650 and the insulating layer 620 may have different areas. For example, as shown in FIG. 5, the mixed layer 650 may have a smaller area than the insulating layer 620. In addition, as shown in FIG. 6, the 2D material layer 640 may be patterned. In this case, the 2D material layer 640 may have an exposure pattern through which a lower surface of the gate electrode 660 is exposed.

The case in which the 2D material layer 640 is provided only between the gate electrode 660 and the mixed layer 650 is described above. However, embodiments are not limited thereto. For example, the 2D material layer 640 may be provided between the gate electrode 660 and the mixed layer 650, and another 2D material layer may be provided between the intermediate electrode 630 and the mixed layer 650.

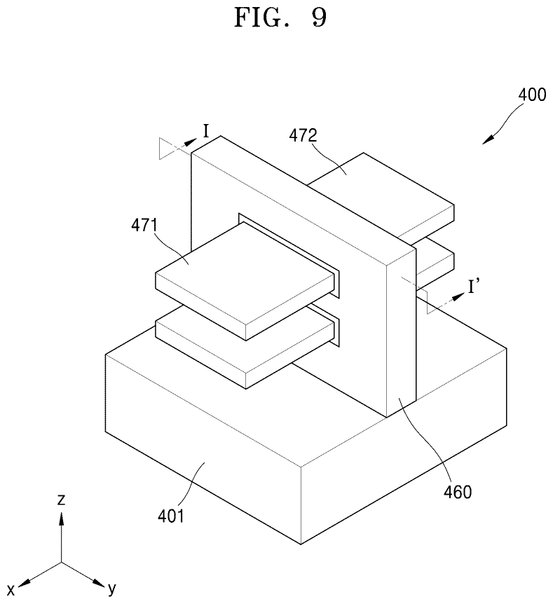

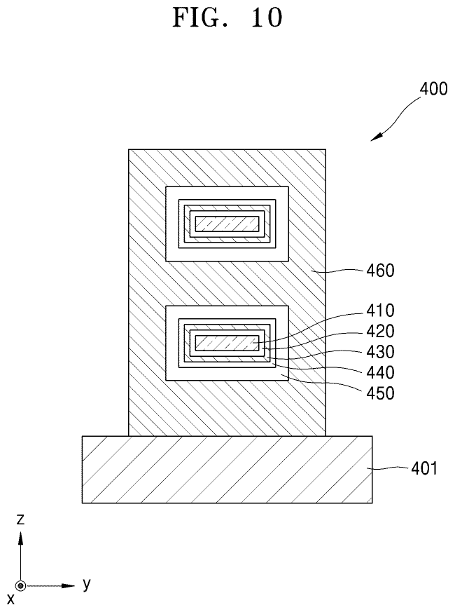

FIG. 9 is a perspective view illustrating a semiconductor device 400 according to another embodiment, and FIG. 10 is a cross-sectional view taken along line I-I′ of FIG. 9. The semiconductor device 400 illustrated in FIG. 9 may be an FeFET having a multi-bridge channel (MBC) structure.

Referring to FIGS. 9 and 10, a plurality of channel layers 410 are provided apart from an upper portion of a substrate 401. FIGS. 9 and 10 show an example in which two channel layers 410 are vertically arranged above the substrate 401. However, this is merely illustrative, and the two channel layers 410 may be horizontally arranged. A source electrode 471 and a drain electrode 472 may be provided on both sides of each of the channel layers 410.

An insulating layer 420, an intermediate electrode 430, a 2D material layer 440, and a mixed layer 450 are sequentially stacked on each of the channel layers 410 to surround the channel layer 410. Here, the mixed layer 450 may include a discontinuous ferroelectric and a low-k dielectric material filled between regions of the ferroelectric, as described above. A gate electrode 460 is provided outside the mixed layer 450 to surround each of the channel layers 410. The gate electrode 460 may surround all four sides of each of the channel layers 410. The insulating layer 420, the intermediate electrode 430, the 2D material layer 440, the mixed layer 450, and the gate electrode 460 are provided as described above, and thus, repeated descriptions thereof are omitted.

An example in which the 2D material layer 440 is provided between the intermediate electrode 430 and the mixed layer 450 is described above. However, embodiments are not limited thereto. It is also possible to provide the 2D material layer 440 between the gate electrode 460 and the mixed layer 450, or to provide the 2D material layer 440 between the intermediate electrode 430 and the mixed layer 450 and another 2D material layer 440 between the gate electrode 460 and the mixed layer 450. In addition, the 2D material layer 440 may be patterned to expose the intermediate electrode 430 or the gate electrode 460.

Each of the semiconductor devices 100, 200, 300, 400, and 600 of the embodiments described above may be applied to each of a plurality of memory cells of a memory device.

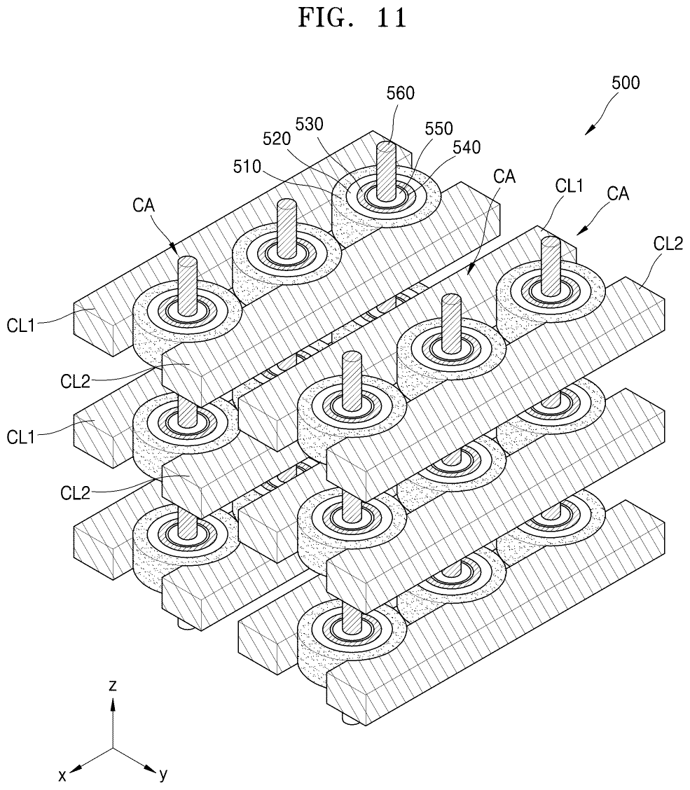

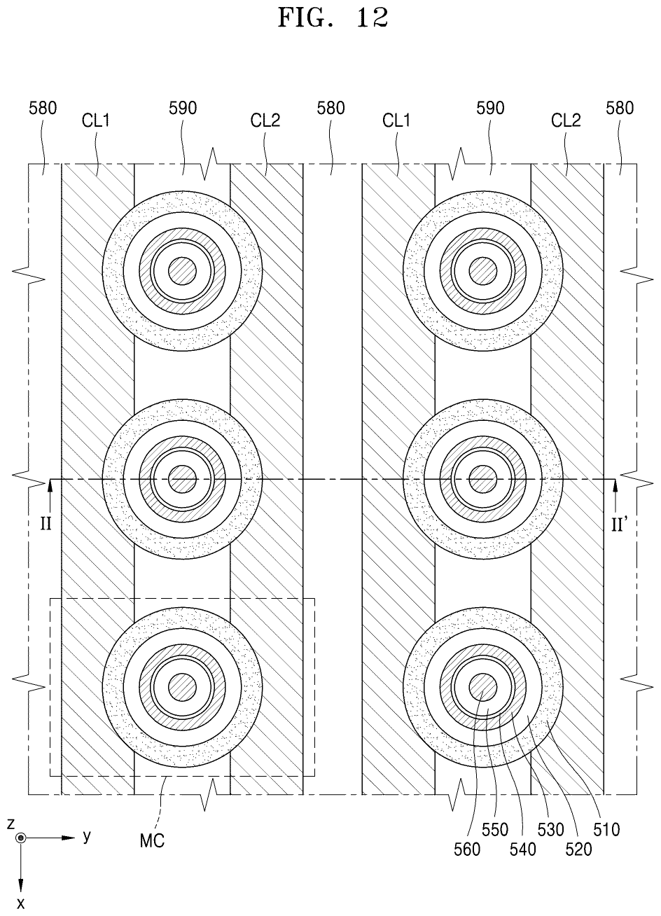

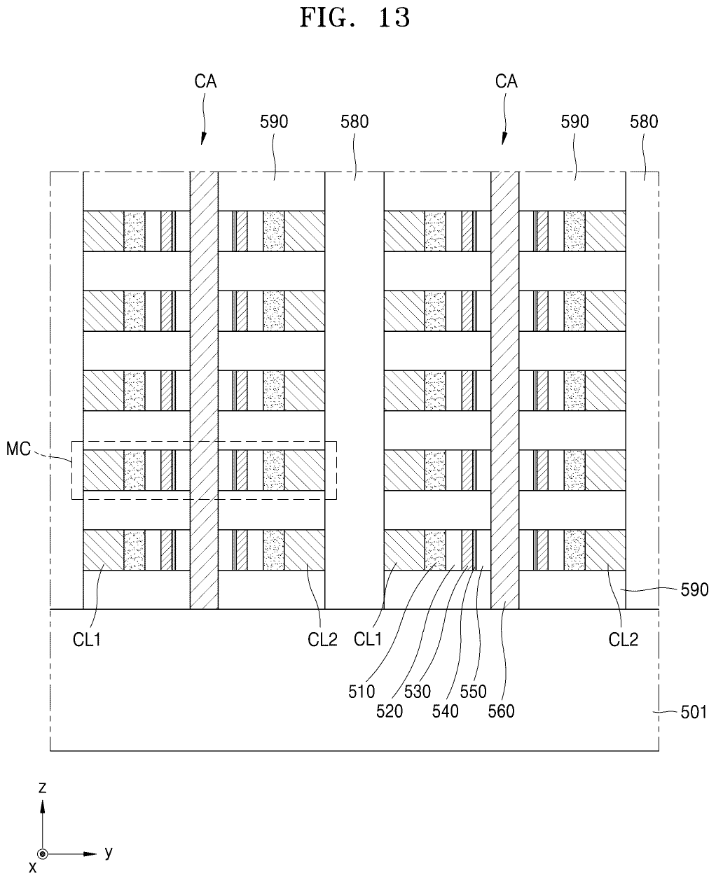

FIG. 11 is a perspective view illustrating a memory device 500 according to at least one embodiment. FIG. 12 is a plan view illustrating the memory device 500 shown in FIG. 11. FIG. 13 is a cross-sectional view taken along line II-II′ of FIG. 12. The differences from the previous embodiments are mainly described below.

Referring to FIGS. 11 to 13, the memory device 500 includes a plurality of cell arrays CA that are two-dimensionally arranged on a substrate 501. FIG. 11 illustrates an example in which the cell arrays CA are arranged in a first direction (x-axis direction) and a second direction (y-axis direction) that are parallel to the substrate 501.

Each of the cell arrays CA may extend in a direction (z-axis direction) perpendicular to the substrate 501. Each of the cell arrays CA may include a plurality of memory cells MC arranged apart from each other in the direction (z-axis direction) perpendicular to the substrate 501. Each of the memory cells MC may include any one of the semiconductor devices 100, 200, 300, 400, and 600 (FeFETs with an MFMIS structure) of the embodiments described above.

A first conductive line CL1 and a second conductive line CL2 are provided on both sides of a plurality of memory cells MC arranged apart from each other in the first direction (x-axis direction) parallel to the substrate 501. For example, the first and second conductive lines CL1 and CL2 may serve as a source electrode and a drain electrode, respectively. Each of the first and second conductive lines CL1 and CL2 may be shared by the memory cells MC arranged in the first direction (x-axis direction). A first insulating material 580 may be provided between cell arrays CA arranged apart from each other in the second direction (y-axis direction) parallel to the substrate 501. A second insulating material 590 may be provided between memory cells MC arranged apart from each other in the direction (z-axis direction) perpendicular to the substrate 501. In addition, the second insulating material 590 may surround the memory cells MC and fill a region between the first and second conductive lines CL1 and CL2.

The substrate 501 may include various materials. For example, the substrate 501 may include a single-crystal silicon substrate, a compound semiconductor substrate, or a silicon-on-insulator (SOI) substrate, but is not limited thereto. In addition, the substrate 501 may further include, for example, a dopant region doped with a dopant, electronic devices such as transistors, or a periphery circuit for selecting and controlling memory cells MC that store data.

Each of the memory cells MC has a structure in which a gate electrode 560, a mixed layer 550, a 2D material layer 540, an intermediate electrode 530, an insulating layer 520, and a channel layer 510 are sequentially stacked in a direction parallel to the substrate 501. Here, the gate electrode 560 may extend vertically from the substrate 501 and may be shared by memory cells MC of a cell array CA. The mixed layer 550, the 2D material layer 540, the intermediate electrode 530, the insulating layer 520, and the channel layer 510 may each be formed in a cylindrical shape surrounding the gate electrode 560.

The gate electrode 560 may include a conductive material. For example, the gate electrode 560 may include a metal, a metal nitride, a metal oxide, polysilicon, a metal carbide, a 2D conductive material and/or a conductive combination thereof. For example, the gate electrode 560 may include at least one selected from W, TiN, TaN, WN, NbN, Mo, Ru, Ir, RuO, IrO, and heavily doped polysilicon.

The channel layer 510 may include, for example, an elemental semiconductor (e.g., a Group IV semiconductor such as Si, Ge, or SiGe), a compound semiconductor (e.g., a Group III-V compound semiconductor) an oxide semiconductor, a nitride semiconductor, an oxynitride semiconductor, a 2D semiconductor material, quantum dots, and/or an organic semiconductor. However, this is merely illustrative, and embodiments are not limited thereto. The channel layer 510 may further include a dopant.

The intermediate electrode 530 is provided between the gate electrode 560 and the channel layer 510. Like the gate electrode 560, the intermediate electrode 530 may include a conductive material. For example, the intermediate electrode 530 may include at least one selected from W, TiN, TaN, WN, NbN, Mo, Ru, Ir, RuO, IrO, and polysilicon.

The mixed layer 550 is provided between the intermediate electrode 530 and the gate electrode 560. The mixed layer 550 may include a discontinuous ferroelectric and a low-k dielectric material filled between regions of the discontinuous ferroelectric, as described above. The ferroelectric may include, for example, at least one selected from hafnium oxide (HfO₂), zirconium oxide (ZrO₂), and hafnium-zirconium oxide (HfₓZr₁₋ₓO₂, 0<x<1). The ferroelectric may further include a dopant. The dopant may include, for example, at least one selected from La, Y, Gd, Si, Al, Mg, Sr, and Ba, but it is not limited thereto. The low-k dielectric material may include, for example, at least one selected from SiO₂ and SiOC, but it is not limited thereto. The 2D material layer 540 is provided between the intermediate electrode 530 and the mixed layer 550. The 2D material layer 540 may include, for example, graphene, h-BN, or TMD. However, the 2D material layer 540 is not limited thereto.

The insulating layer 520 is provided between the channel layer 510 and the intermediate electrode 530. The insulating layer 520 may include a high-k dielectric material with a dielectric constant greater than the dielectric constant of the low-k dielectric material. For example, the high-k dielectric material may include at least one selected from HfO₂, ZrO₂, Ta₂O₅, and TiO₂, but it is not limited thereto.

In the memory device 500 each of the memory cells MC includes the mixed layer 550 that is provided between the gate electrode 560 and the intermediate electrode 530 and includes the discontinuous ferroelectric and the low-k dielectric material filled between regions of the discontinuous ferroelectric. This configuration reduces the capacitance of an MFM capacitor formed by the gate electrode 560, the mixed layer 550 including the discontinuous ferroelectric, and the intermediate electrode 530, thereby increasing the MW of each of the memory cells MC.

An example in which the 2D material layer 540 is provided between the intermediate electrode 530 and the mixed layer 550 is described above. However, embodiments are not limited thereto, and it is also possible to provide the 2D material layer 540 between the gate electrode 560 and the mixed layer 550. In addition, the 2D material layer 540 may be patterned to expose the intermediate electrode 530 or the gate electrode 560.

In the example shown in FIGS. 11 to 13, the mixed layer 550, the 2D material layer 540, the intermediate electrode 530, the insulating layer 520, and the channel layer 510 that sequentially surround the gate electrode 560 are divided in units of memory cells MC in the direction (z-axis direction) perpendicular to the substrate 501. However, the embodiments are not limited thereto. For example, the mixed layer 550, the 2D material layer 540, the intermediate electrode 530, the insulating layer 520, and the channel layer 510 may all be provided in common for a plurality of memory cells MC in the direction (z-axis direction) perpendicular to the substrate 501. In another example, some of the mixed layer 550, the 2D material layer 540, the intermediate electrode 530, the insulating layer 520, and the channel layer 510 may be divided in units of memory cells MC in the direction (z-axis direction) perpendicular to the substrate 501.

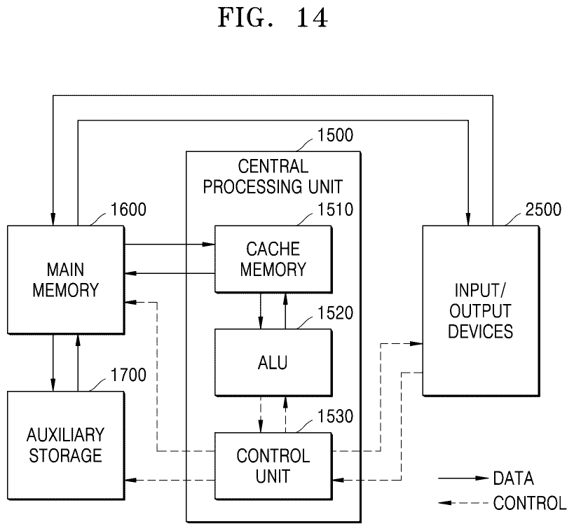

The semiconductor devices 100, 200, 300, 400, and 600, and the memory device 500 of the embodiments described above may be used to store data in various electronic devices. FIG. 14 is a conceptual view schematically illustrating a device architecture that may be applied to electronic devices according to embodiments.

Referring to FIG. 14, a cache memory 1510, an arithmetic logic unit (ALU) 1520, and a control unit 1530 may form a central processing unit (CPU) 1500. The cache memory 1510 may include a static random-access memory (SRAM). A main memory 1600 and an auxiliary storage 1700 may be provided separately from the CPU 1500. The main memory 1600 may include a dynamic random-access memory (DRAM) device, and the auxiliary storage 1700 may include the memory device 500. Input/Output devices 2500 may be provided. In some cases, the device architecture may be implemented in the form in which unit computing devices and unit memory devices are adjacent to each other on one chip without any distinction between sub-units. The semiconductor devices 100, 200, 300, 400, and 600, and the memory device 500 of the embodiments described above may be included, e.g., in at least one of the main memory 1600, the auxiliary storage 1700, and/or the CPU 1500.

The memory device 500 of the embodiment described above may be implemented as a chip-type memory block and used as a neuromorphic computing platform or may be used to construct a neural network.

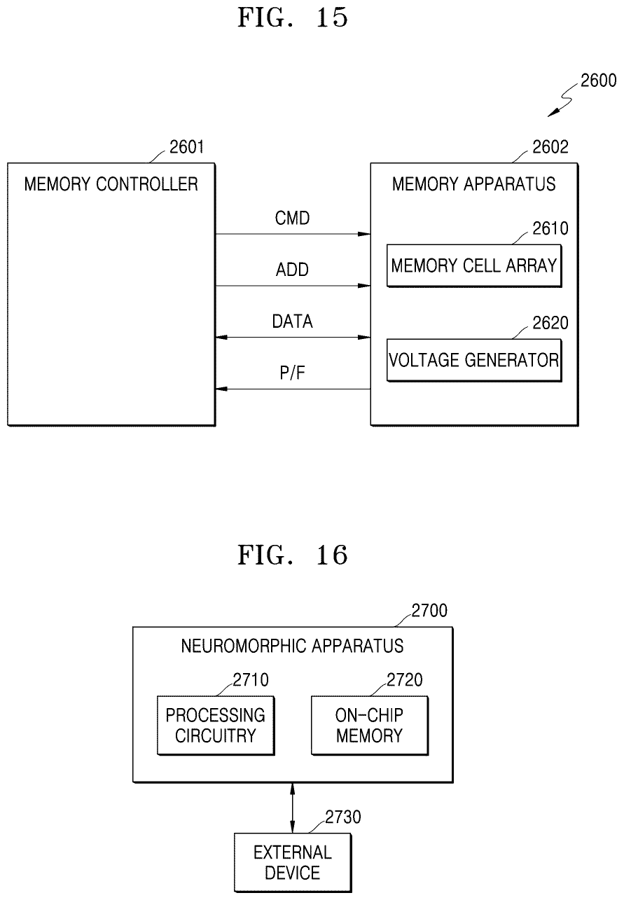

FIG. 15 is a block diagram illustrating a memory system 2600 according to at least one embodiment.

Referring to FIG. 15, the memory system 2600 may include a memory controller 2601 and a memory apparatus 2602. The memory controller 2601 performs a control operation on the memory apparatus 2602. For example, the memory controller 2601 provides, to the memory apparatus 2602, an address ADD and a command CMD for performing programming (or write), read, and/or erase operations on the memory apparatus 2602. In addition, data for a programing operation and read data may be transmitted between the memory controller 2601 and the memory apparatus 2602.

The memory apparatus 2602 may include a memory cell array 2610 and a voltage generator 2620. The memory cell array 2610 may include a plurality of memory cells and/or the memory device 500 of the embodiment described above. For example, the memory cell array 2610 may include at least one of the semiconductor devices 100, 200, 300, 400, and 600 described above.

The memory controller 2601 may include processing circuitry such as hardware including a logic circuit; a hardware/software combination such as processor execution software; or a combination thereof. Examples of the processing circuitry may include a central processing unit (CPU), an arithmetic logic unit (ALU), a digital signal processor, a microcomputer, a field-programmable gate array (FPGA), a system-on-chip (SoC), a programmable logic unit, a microprocessor, and an application-specific integrated circuit (ASIC), but are not limited thereto. The memory controller 2601 may operate in response to a request from a host (not shown), and may be configured to change into a special purpose controller by accessing to the memory apparatus 2602 and controlling a control operation (for example, a write/read operation) discussed above. The memory controller 2601 may generate an address ADD and a command CMD for performing a programming/read/erase operation on the memory cell array 2610. In addition, in response to a command from the memory controller 2601, the voltage generator 2620 (for example, a power circuit) may generate a voltage control signal for controlling a voltage level of a word line to program data in the memory cell array 2610 or read data from the memory cell array 2610.

In addition, the memory controller 2601 may perform a determination operation on data read from the memory apparatus 2602. For example, the number of on-cells and/or the number of off-cells may be determined based on data read from a memory cell. The memory apparatus 2602 may provide a pass/fail signal P/F to the memory controller 2601 according to results of data reading. The memory controller 2601 may control write and read operations of the memory cell array 2610 with reference to the pass/fail signal P/F.

FIG. 16 is a block diagram illustrating a neuromorphic apparatus 2700 and an external device 2730 connected to the neuromorphic apparatus 2700, according to at least one embodiment.

Referring to FIG. 16, the neuromorphic apparatus 2700 may include processing circuitry 2710 and/or an on-chip memory 2720. The neuromorphic apparatus 2700 may include the memory device 500 of the embodiment described above and/or the semiconductor devices 100, 200, 300, 400, and 600, and the memory device 500 of the embodiments described above.

In some embodiments, the processing circuitry 2710 may be configured to control a function for driving the neuromorphic apparatus 2700. For example, the processing circuitry 2710 may be configured to control the neuromorphic apparatus 2700 by executing a program stored in the memory 2720. In some embodiments, the processing circuitry 2710 may include hardware such as a logic circuit, a hardware/software combination such as a processor configured to execute software, or a combination thereof. For example, the processor may include a CPU, a graphics processing unit (GPU), an application processor (AP) included in the neuromorphic apparatus 2700, an ALU, a digital signal processor, a microcomputer, a FPGA, a SoC, a programmable logic unit, a microprocessor, and an ASIC, but is not limited thereto. In some embodiments, the processing circuitry 2710 may read/write various data with respect to the external device 2730, and/or may be configured to execute the neuromorphic apparatus 2700 using the read/written data. In some embodiments, the external device 2730 may include an external memory and/or a sensor array having an image sensor (for example, a complementary metal-oxide-semiconductor (CMOS) image sensor circuit).

In some embodiments, the neuromorphic apparatus 2700 shown in FIG. 16 may be applied to a machine learning system. The machine learning system may use various artificial neural network organizing and processing models such as a convolutional neural network (CNN), a deconvolutional neural network, a recurrent neural network (RNN) including a long short-term memory (LSTM) unit and/or a gated recurrent unit (GRU), a stacked neural network (SNN), a state-space dynamic neural network (SSDNN), a deep belief network (DBN), a generative adversarial network, and/or a restricted Boltzmann machine (RBM).

Alternatively or additionally, the machine learning system may include other forms of machine learning models, for example, linear and/or logistic regression, statistical clustering, Bayesian classification, decision tree, dimensionality reduction such as principal component analysis, an expert system, and/or a combination thereof including ensembles such as random forests. These machine learning models may be used to provide various services and/or applications. For example, an image classification service, a user authentication service based on biometrics or biometric data, an advanced driver assistance system (ADAS) service, a voice assistant service, or an automatic speech recognition (ASR) service may be executed by an electronic device.

In each of the semiconductor devices 100, 200, 300, 400, and 600 of the embodiments, the mixed layer including the discontinuous ferroelectric and the low-k dielectric material filled between regions of the discontinuous ferroelectric is provided between the gate electrode and the intermediate electrode, and thus, the capacitance C_{FE} of the MFM capacitor formed by the gate electrode, the mixed layer including the discontinuous ferroelectric, and the intermediate electrode may be reduced. For example, the mixed layer provided between the gate electrode and the intermediate electrode includes the discontinuous ferroelectric, and the discontinuous ferroelectric has an effect of connecting the gate electrode and the intermediate electrode in parallel to each other, thereby reducing the capacitance C_{FE} of the MFM capacitor. As a result, the MW of the semiconductor device may be increased.

While the semiconductor devices 100, 200, 300, 400, and 600, and the memory device 500 have been described with reference to the accompanying drawings in which embodiments are shown, the embodiments are merely examples, and it will be understood by those of ordinary skill in the art that various modifications may be made in the embodiments.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer;
a gate electrode spaced apart from the channel layer;
an insulating layer between the channel layer and the gate electrode;
an intermediate electrode between the insulating layer and the gate electrode;
a mixed layer between the intermediate electrode and the gate electrode, the mixed layer comprising a discontinuous ferroelectric and a low-k dielectric material between regions of the discontinuous ferroelectric, the low-k dielectric material having a dielectric constant less than a dielectric constant of the discontinuous ferroelectric; and a two-dimensional (2D) material layer between the mixed layer and at least one of the intermediate electrode or the gate electrode.

2. The semiconductor device of claim 1, wherein the discontinuous ferroelectric comprises a ferroelectric phase of at least one of HfO₂, ZrO₂, or HfₓZr₁₋ₓO₂ (0<x<1) as a dominant phase.

3. The semiconductor device of claim 2, wherein the discontinuous ferroelectric further comprises a dopant.

4. The semiconductor device of claim 3, wherein the dopant comprises at least one of lanthanum (La), yttrium (Y), gadolinium (Gd), silicon (Si), aluminum (Al), magnesium (Mg), strontium (Sr), or barium (Ba).

5. The semiconductor device of claim 1, wherein an area proportion of the discontinuous ferroelectric in the mixed layer is included in a range of about 0.1 to about 0.8.

6. The semiconductor device of claim 1, wherein the low-k dielectric material comprises at least one of SiO₂ or SiOC.

7. The semiconductor device of claim 1, wherein the insulating layer comprises a high-k dielectric material having a dielectric constant greater than the dielectric constant of the low-k dielectric material.

8. The semiconductor device of claim 7, wherein the high-k dielectric material comprises at least one of HfO₂, ZrO₂, Ta₂O₅, or TiO₂.

9. The semiconductor device of claim 1, wherein the 2D material layer comprises at least one of graphene, a transition metal dichalcogenide (TMD), or hexagonal boron nitride (h-BN).

10. The semiconductor device of claim 1, wherein the mixed layer has a different area from the insulating layer when viewed in a plan view.

11. The semiconductor device of claim 1, wherein the 2D material layer comprises an exposure pattern exposing the intermediate electrode or the gate electrode.

12. A memory device comprising:
a plurality of memory cells arranged in a direction perpendicular to a substrate each of the plurality of memory cells comprises
a channel layer,
a gate electrode spaced apart from the channel layer and extending in the direction perpendicular to the substrate,
an insulating layer between the channel layer and the gate electrode,
an intermediate electrode between the insulating layer and the gate electrode,
a mixed layer between the intermediate electrode and the gate electrode, the mixed layer comprising a discontinuous ferroelectric and a low-k dielectric material, the discontinuous ferroelectric being provided on the gate electrode, the low-k dielectric material being filled between regions of the discontinuous ferroelectric and having a dielectric constant less than a dielectric constant of the discontinuous ferroelectric, and
a two-dimensional (2D) material layer between the mixed layer and at least one of the intermediate electrode or the gate electrode.

13. The memory device of claim 12, wherein the discontinuous ferroelectric comprises a ferroelectric phase of at least one of HfO₂, ZrO₂, or HfₓZr₁₋ₓO₂ (0<x<1) as a dominant phase.

14. The memory device of claim 13, wherein the discontinuous ferroelectric further comprises a dopant.

15. The memory device of claim 12, wherein the insulating layer comprises a high-k dielectric material having a dielectric constant greater than the dielectric constant of the low-k dielectric material.

16. The memory device of claim 12, wherein the 2D material layer comprises at least one of graphene, a transition metal dichalcogenide (TMD), or hexagonal boron nitride (h-BN).

17. The memory device of claim 12, wherein the 2D material layer comprises an exposure pattern exposing the intermediate electrode or the gate electrode.

18. A method of manufacturing a mixed layer in a semiconductor device comprising a channel layer, an insulating layer, an intermediate electrode, the mixed layer, and a gate electrode sequentially stacked, the method comprising:
depositing a 2D material layer on at least one of the intermediate electrode or the gate electrode; and
forming the mixed layer on the 2D material layer,
wherein the forming of the mixed layer comprises
growing a ferroelectric discontinuously on the 2D material layer, and
forming a low-k dielectric material between regions of the discontinuously-grown ferroelectric.

19. The method of claim 18, wherein the 2D material layer comprises graphene, transition metal dichalcogenide (TMD), or hexagonal boron nitride (h-BN).

20. The method of claim 18, wherein the ferroelectric comprises at least one of HfO₂, ZrO₂ and HfₓZr₁₋ₓO₂ (0<x<1).
